(19) United States
(12) Patent Application Publication
(10) Pub. No.: US 2025/0384193 A1
(43) Pub. Date: Dec. 18, 2025

(54) CIRCUIT DESIGN USING A BOOLEAN SATISFIABILITY SOLVER

(71) Applicant: GDM Holding LLC, Mountain View, CA (US)

(72) Inventor: Matthew L. Ginsberg, Eugene, OR (US)

(21) Appl. No.: 19/237,470

(22) Filed: Jun. 13, 2025

Related U.S. Application Data
(60) Provisional application No. 63/659,821, filed on Jun. 13, 2024.

(51) Int. Cl. G06F 30/31

(52) U.S. Cl. CPC G06F 30/31

(57) ABSTRACT

Methods, systems, and apparatus, including computer-readable media, for circuit design using a Boolean satisfiability solver. In some implementations, a system accesses circuit data describing circuit behavior or logic for a circuit to be designed. The system generates one or more Boolean expressions with variables that each represent a different design characteristic for the circuit. The system defines a Boolean satisfiability problem for the class of circuits having a predetermined circuit size, where the Boolean satisfiability problem has criteria that include (i) the generated one or more Boolean expressions and (ii) an assertion that the circuit is faulted. The system uses a Boolean satisfiability solver to process the Boolean satisfiability problem, and after determining that the Boolean satisfiability problem is unsatisfiable, the system uses the Boolean satisfiability solver to solve a series of updated versions of the Boolean satisfiability problem, and the system generates circuit design parameters for the circuit.

### CROSS-REFERENCE TO RELATED APPLICATIONS

This application claims the benefit of priority to U.S. Provisional Patent Application No. 63/659,821, filed on Jun. 13, 2024, the entire contents of which is hereby incorporated by reference in its entirety.

### BACKGROUND

The present specification relates to techniques for designing circuits using a Boolean satisfiability solver, e.g., a SAT solver.

In general, Boolean satisfiability problems ask whether the variables of a given Boolean formula can be replaced by the values “true” or “false” in a way that the formula evaluates to “true.” If this condition can be achieved, the formula is considered to be satisfiable. On the other hand, if there exists no assignment of Boolean values that evaluates to “true,” the function expressed by the formula is “false” for all possible variable assignments and the formula is considered to be unsatisfiable. Computer programs and algorithms have been designed to act as Boolean satisfiability solvers, commonly referred to as SAT solvers, to determine whether a Boolean formula is satisfiable.

### SUMMARY

In some implementations, a system is configured to perform circuit design and circuit validation tasks using a Boolean satisfiability engine, e.g., a SAT solver. The system can create an analysis problem for a SAT solver that expresses a range of potential circuit designs having certain characteristics (such as a particular number of transistors) as a Boolean formula. Variables in the formula can each represent a corresponding binary design choice, such as whether to electrically connect a particular pair of nodes or terminals in a circuit. The system can also store data indicating the desired behavior or logic of the circuit, e.g., using a truth table or other format. The system then adds to the analysis problem an assertion that the circuit design is faulted, e.g., fails to provide the desired behavior or logic. This enables the processing of single satisfiability problem to represent an entire class of circuit designs. The system then applies a SAT solver to the analysis problem.

Unlike typical approaches, because of the assertion that the circuit design is faulted, an analysis result of “unsatisfiable” indicates that a valid circuit has been found. If the SAT solver classifies the problem as unsatisfiable, this means that the circuit is not faulted under all possible combinations of Boolean values for the circuit design decisions, and thus that a combination of connections exists so that the circuit that is not faulted. In other words, a result of unsatisfiable represents that a set of design decisions has been found that does not satisfy the circuit fault condition and is therefore a valid circuit design. Accordingly, when the system finds that the analysis problem formulated in this way has a result of unsatisfiable, the system can identify the combination of values that did not produce a fault as valid for further circuit design and optimization.

In general, circuit design is often thought of as being in a class of problems known as Σ_{P}². Typically, systems have applied an approach to generate a variety of candidate designs and then check each candidate design with a SAT solver or other analysis. This often involves making a large number of analysis requests to the SAT solver, so that each different design can be assessed, until one is found to satisfy all of the conditions. By contrast, the present document describes a technique that can solve the problem with far fewer requests to the SAT solver, and in some cases a single request or analysis process for a set of design parameters.

As an example, the system can be used to efficiently generate circuit designs and to optimize the parameters for the circuit. In many cases, circuit designs that use fewer components are more desirable (e.g., for lower cost, lower power consumption, lower space requirements, faster processing). Using a modified SAT solver, the system can determine the minimum size capable of implementing a circuit (e.g., a minimum number of transistors, logic gates, etc.) and generate a circuit design for the minimum size. The SAT solver is modified to retain information about its results across the search space, even after a classification of satisfiable or unsatisfiable is determined. This feature enables the SAT solver to maintain its state or pause without losing the accumulated results for portions of the search space that have been analyzed. The system makes use of this capability to efficiently optimize the size of a circuit.

For example, the system can use a SAT solver to solve a satisfiability problem representing a particular circuit size (e.g., 100 devices, such as 100 transistors or 100 logic gates). Starting with a relatively large circuit size creates a large search space and a circuit design of this size may be significantly larger than is needed for the logic to be implemented. Nevertheless, when a successful circuit design is found, the SAT solver saves its calculation results for the search space and the processing work done to analyze the space can be reused for further optimization. The system then incrementally tests smaller circuit sizes by building on the analysis results already calculated and retained by the SAT solver. The system tests smaller circuit sizes by updating the satisfiability problem to progressively add assertions that constrain the size of the circuit. For example, after finding that a valid design is possible for 100 transistors, the system adds an assertion that one of the transistors is disconnected (e.g., any one of the transistors, or a particular one such as the 100^{th} transistor). This maintains the same search space as the original satisfiability problem for 100 transistors, but narrows the possible solution to use 99 transistors or fewer. If a valid circuit design is found using 99 transistors, then the problem is updated to specify that at least two transistors are disconnected, and so on. This process can proceed until a size is reached in which no valid circuit design is found, and so the previously tested size is known to be optimal.

With this technique, the system can effectively prune or filter the search space incrementally by progressively updating the satisfiability problem with assertions that incrementally shrink the allowed size of circuit designs. The process is very efficient because the SAT solver maintains the same search space and retains the processing results across each of the updates. Although a significant amount of processing is performed initially for a large circuit size, the amount of processing for each incremental optimization iteration is limited. The processing to find at least one circuit for the larger problem (e.g., 100 transistors) has already examined and classified done much of the work for smaller problems encompassed within the search space (e.g., 99 transistors, 98 transistors, 97 transistors, etc.). Naturally, a solution found using 100 transistors will be different from a solution that uses 95 transistors, so there will be additional processing performed for each update. Nevertheless, portions of the search space that the SAT solver is able to rule out or verify can be reused to reduce the amount of computation for processing that constrains the size further.

The system can improve the analysis of circuit design by performing the analysis with a complexity class of co-NP, or the complement of nondeterministic polynomial time (NP). This can provide efficiency benefits. In some cases, a SAT solver can include optimizations or algorithms that enable it to identify unsatisfiability more quickly than satisfiability, at least in some cases. Further, framing the analysis problem where unsatisfiability is desirable can reduce the number of requests to the SAT solver and thus reduce the number of analysis problems processed, which reduces overhead and can allow for additional optimization.

In many prior systems, tools that perform automated circuit design use encodings that increase in size exponentially with the number of inputs to the circuit in question. The exponential size relationship can cause exponential increases in the size or complexity of the solution methods, leading to unacceptable performance. For example, previous systems that have tried to use a SAT solver to verify individual circuit designs often involve a request to the SAT solver for each design to be tested. This can result in an increase in the number of requests to the SAT solver as the design that is exponential with respect to the size of the circuit, so the amount of requests increases exponentially with linear increases in circuit size.

In one general aspect, a method of electronic design automation performed by one or more computers includes: accessing, by the one or more computers, circuit data describing circuit behavior or logic for a circuit to be designed; generating, by the one or more computers, one or more Boolean expressions with variables that each represent a different design characteristic for the circuit, wherein, for each of at least some of the variables, the variable represents a decision whether a connection is made between a corresponding pair of nodes in the circuit; defining, by the one or more computers, a Boolean satisfiability problem for the class of circuits having a predetermined circuit size, wherein the Boolean satisfiability problem has criteria that include (i) the generated one or more Boolean expressions and (ii) an assertion that the circuit is faulted; using, by the one or more computers, a Boolean satisfiability solver to process the Boolean satisfiability problem; after the Boolean satisfiability solver indicates that the Boolean satisfiability problem is unsatisfiable, using, by the one or more computers, the Boolean satisfiability solver to solve a series of updated versions of the Boolean satisfiability problem, wherein the updated versions of the Boolean satisfiability problem progressively reduce the circuit size compared to the previous version of the Boolean satisfiability problem while maintaining a search space of the Boolean satisfiability problem, and wherein the Boolean satisfiability solver is configured to store analysis results for the search space and to use the stored analysis results to perform the updated versions of the Boolean satisfiability problem; and generating, by the one or more computers, circuit design parameters for the circuit based on results of a processing iteration for which the corresponding version of the Boolean satisfiability problem is determined to be unsatisfiable based on the processing of the Boolean satisfiability solver.

In some implementations, the assertion that the circuit is faulted is an assertion that the circuit is faulted for each combination of values for the variables.

In some implementations, using the Boolean satisfiability solver to solve the series of updated versions of the Boolean satisfiability problem comprises: processing updated versions of the Boolean satisfiability problem for progressively smaller circuit sizes until obtaining a result for an updated version of the Boolean satisfiability problem that is indicated to be satisfiable based on the processing of the Boolean satisfiability solver; wherein the generated circuit design parameters comprise a circuit design determined for the smallest circuit size for which the corresponding updated version of the Boolean satisfiability problem is determined to be unsatisfiable.

In some implementations, the updated versions of the Boolean satisfiability problem each add an assertion that an additional element of the circuit is disconnected or unused.

In some implementations, the predetermined circuit size is a predetermined number of transistors or logic gates; and the series of updated versions of the Boolean satisfiability problem is a series of series of updated versions of the Boolean satisfiability problem that respectively include assertions that progressively greater numbers of transistors or logic gates, of the predetermined number of transistors or logic gates, be disconnected or unused.

In some implementations, generating the circuit design parameters comprises selecting a circuit size corresponding to the processing iteration for the smallest circuit size for which the corresponding updated version of the Boolean satisfiability problem is determined to be unsatisfiable.

In some implementations, generating the circuit design parameters comprises: identifying, for the processing iteration for the smallest circuit size for which the corresponding updated version of the Boolean satisfiability problem is determined to be unsatisfiable, a combination of values for the variables of the Boolean expressions for the corresponding Boolean satisfiability problem that does not satisfy the assertion that the circuit is faulted; and generating data indicating a set of connections among nodes in the circuit based on the identified combination of values.

In some implementations, the circuit data comprises combinatorial logic for the circuit or a truth table for the circuit.

In some implementations, the assertion that the circuit is faulted is a requirement that the Boolean satisfiability problem is satisfiable only if there is no combination of values for the variables for which all combinations of the inputs would produce the circuit behavior or logic indicated by the circuit data.

In some implementations, using the Boolean satisfiability solver to process the Boolean satisfiability problem comprises: evaluating different combinations of values for the variables representing different design characteristics, including, for each combination of values of the different combinations of values: evaluating multiple combinations of circuit input values to determine whether, for a circuit having the set of design characteristics indicated by the combination values, each of the multiple combinations of circuit input values would result in circuit output that is specified for the circuit by the circuit data.

In some implementations, accessing a set of design rules for the circuit; and using the design rules to (i) generate one or more of the Boolean expressions in the sets of Boolean expressions or (ii) limit a set of combinations of values for the variables of the Boolean expressions.

The details of one or more embodiments of the invention are set forth in the accompanying drawings and the description below. Other features and advantages of the invention will become apparent from the description, the drawings, and the claims.

### BRIEF DESCRIPTION OF THE DRAWINGS

FIG. 1 is a diagram showing an example of a system for performing circuit design using a Boolean satisfiability solver (e.g., SAT solver).

FIG. 2 is a diagram showing an example of circuit design using a SAT solver.

FIG. 3 is a diagram showing an example of a binary tree representing a search space for circuit design using a SAT solver.

Like reference numbers and designations in the various drawings indicate like elements.

### DETAILED DESCRIPTION

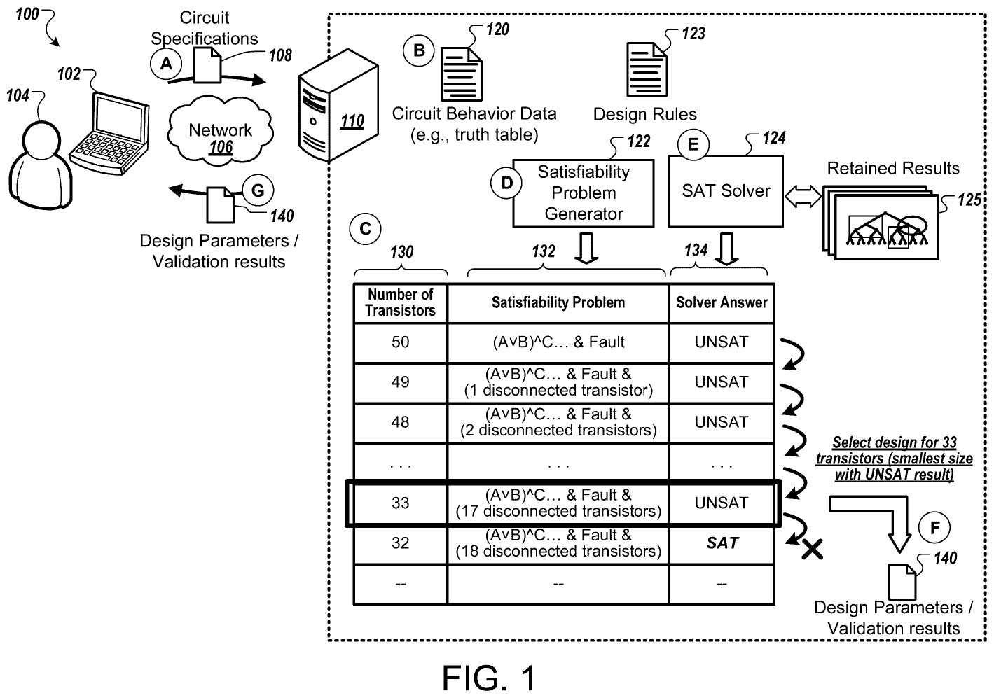

FIG. 1 is a diagram showing an example of a system 100 for performing circuit design using a Boolean satisfiability solver, e.g., a SAT solver 124. The system 100 includes a computer system 110 that is configured to use the SAT solver 124 to generate, optimize, or verify circuit designs. The computer system 110 can communicate with a remote device 102 over a communication network 106 to receive design tasks, circuit specifications, and other instructions from a user 104.

The example of FIG. 1 shows a series of stages (A) to (G) that illustrate a flow of data and various operations or functions performed in the system. The operations of stages (A) to (G) can be performed in the order shown, or in another order, and the techniques can be used advantageously with steps removed or with additional steps added.

The techniques described herein can be applied to accomplish a wide variety of tasks in the field of circuit design, including generating new circuit designs, design verification, circuit optimization, circuit validation or verification, and so on. Similarly, the techniques can be used to determine values for any of various circuit parameters, such as the number of devices (e.g., transistors, logic gates, modules), the types of devices (e.g., how many PMOS transistors, NMOS transistors, etc.), the connections to be established between nodes or terminals in the circuit, placement and routing, and so on. The techniques can be used to generate or verify a circuit design according to various different constraints, such as functional verification (e.g., logic accuracy), size constraints, area constraints, timing constraints, power constraints, and so on. Similarly, the illustrated example focuses on the design and verification of digital logic circuits, but the same techniques may be applied to design and verify characteristics of analog and mixed-signal circuits also.

For clarity in illustration and description, the example of FIG. 1 shows processing to determine the value of a parameter for a circuit design, the minimum number of transistors needed to provide the logic specified, and to determine a circuit design with this optimized parameter. To generate or verify configuration information that sets other parameters or satisfies additional constraints for the circuit, additional iterations or rounds of operations of stages (B) to (F) can be performed, focusing on different circuit characteristics or constraints.

For example, the processing illustrated in FIG. 1 is used to determine the minimum number of devices that can provide accurate combinatorial logic, as well as the wiring or connections among the devices that can achieve that logic. The Boolean satisfiability problems 132 that are formulated and solved by the computer system 110 use Boolean variables to represent potential connections between nodes or terminals in the circuit. After the illustrated process is complete and one or more designs are found that provide accurate logic, additional processing can be used to optionally solve Boolean satisfiability problems that represent other constraints for placement, routing, area, power consumption, frequency performance, signal timing, and so on. In other words, in the same manner that the illustrated example generates or verifies parameters of transistor count and connections among transistors or logic gates, additional rounds of processing can generate or verify characteristics to achieve signal propagation timing that meets constraints or maximizes frequency potential, placement or routing that minimizes area usage, or determines other circuit properties.

In the example of FIG. 1, in stage (A), a user 104 specifies the characteristics desired for a circuit to be designed (or for a circuit to be verified or optimized), and the user's device 102 sends circuit specifications 108 indicating these characteristics to the computer system 110 over the communication network 106, such as the Internet. The user 104 can enter a variety of different constraints or requirements for a circuit. In the example, the user 104 specifies features such as the number of inputs, the number of outputs, and combinatorial logic or circuit behavior. The user 104 can indicate the circuit specifications 108 using any of various applications, web pages, web applications, files, and so on. In some implementations, the circuit specifications 108 include a truth table specifying desired outputs for the circuit to be designed for each of various combinations of inputs to the circuit. In some implementations, the circuit specifications 108 include expressions that specify combinatorial logic for the circuit. For example, the circuit specifications 108 can be sent using an application programming interface (API) or provided in a standardized format.

In stage (B), the computer system 110 uses the received circuit specifications 108 to generate and store circuit behavior data 120. In the example, the circuit behavior data 120 is a truth table, a set of assertions about inputs and outputs, or other data that specifies the functional, combinatorial logic properties of a circuit. In some implementations, the circuit behavior data 120 is provided in the circuit specification 108. In other implementations, the computer system 110 may translate or convert the circuit specifications 108 to a standardized format for circuit behavior data 120. For example, if the user 104 provided a logic equation, the computer system 110 can generate a corresponding truth table by calculating the output values for each of the different combinations of input values.

In the example, the circuit behavior data 120 specifies the logic desired for the circuit in a way that the computer system 110 can check whether a combination of input values to the circuit produces the correct output values. In other words, the circuit behavior data 120 can specify the logic between the inputs and outputs of the desired circuit, and the computer system 110 can use the circuit behavior data 120 as a reference for correct circuit behavior when generating or verifying designs. The desired behavior can be stated as a set of assertions or implications, such as: if input A=1 and input B=0, then output X=1; if input A=0 and input B=0, then output X=1; and so on.

In stage (C), the computer system 110 determines a parameter to test or optimize for the circuit design, along with a set of values or prioritization or constraint with which to test the parameter. In the example of FIG. 1, the computer system 110 is evaluating the number of transistors needed to provide the logic specified in the circuit behavior data 120. The computer system 110 applies an optimization objective, such as that using fewer transistors is better, e.g., more efficient or more desirable, and so a circuit design with the minimum number of transistors should be identified.

The computer system 110 and the SAT solver 124 are configured to store and efficiently reuse the processing results for one circuit size class to simply analysis for smaller circuit size classes. For example, the SAT solver 124 can be configured to retain results 125 for the search space of a satisfiability problem 132, and then use the retained results 125 to more quickly and efficiently solve additional satisfiability problems 132 for the same circuit behavior (e.g., the same logic described by circuit behavior data 120). The SAT solver is configured to retain its results 125 across the search space, even after a classification of satisfiable or unsatisfiable is determined. This enables the SAT solver 124 to maintain its state, or pause and resume analysis of the search space, without losing the accumulated results for portions of the search space that have been analyzed already.

For example, the system can use a SAT solver to solve a satisfiability problem representing a particular circuit size (e.g., 50 transistors). Starting with a relatively large circuit size creates a large search space and a circuit design of this size may be significantly larger than is needed for the logic to be implemented. Nevertheless, when a successful circuit design is found, the SAT solver 125 saves its calculation results for the search space and the processing work done to analyze the space can be reused for further optimization. The system then incrementally tests smaller circuit sizes (e.g., 49 transistors, 48 transistors, etc.), and the analysis builds on the results 125 already calculated and retained by the SAT solver.

The computer system 110 can select a relatively large circuit size that sets a large search space for circuit designs, one that is likely to include a valid design even if the initial size is greater than is optimal. The search space for the initial circuit size can be maintained and used to test this circuit size as well as smaller circuit sizes.

In stage (D), the computer system 110 uses a satisfiability problem generator 122 to express circuit characteristics in the form of one or more Boolean expressions. For example, the computer system 110 can express a circuit design or set of circuit designs with a Boolean expression or formula that specifies relationships among set of Boolean variables each representing a different characteristic or feature of a circuit. In the example of FIG. 1, each Boolean variable represents a different potential connection (e.g., a wire) between a specific pair of nodes (e.g., inputs, outputs, transistor terminals, power supply rails, ground, or other defined points where a connection may be made), where a “true” or “1” value indicates a wire between the pair and a “false” or “0” value represents no wire connecting the pair. Each device can have multiple nodes or connection points, such as each transistor having a gate, a drain, and a source, which could potentially connect to any of the circuit inputs, circuit outputs, power ground or the gate, drain, or source of any other transistor. As a result, different variables in the Boolean expressions can represent decisions (e.g., binary design choices) whether to include wires between different pairs of nodes in the circuit. In some implementations variables can represent decisions or design choices for other types of circuit characteristics, such as which of multiple types of circuit elements are used (e.g., which type of logic gate to use, or which type of transistor to use, etc.).

In some implementations, each possible connection among circuit elements is represented in the Boolean expression, with a different variable being used for every different pair of nodes. As a result, the Boolean expression generated for a particular number of transistors, e.g., 50 transistors, can represent the set of circuit designs encompassing every permutation of connections (e.g., every different combination and sub-combination of connections) among 50 transistors with the specified inputs and outputs. Changing the values of the Boolean variables changes the set of connections that are present in a hypothetical circuit. As a result, by testing the satisfiability of the Boolean expression across the range of Boolean variable value combinations, the various different design variations that are possible for a particular number of transistors (and/or other types of electrical devices) can be tested. In this manner, the entire class or category of circuits that share a particular design parameter value, such as those that share the same number of transistors, can be evaluated with a single Boolean expression.

The computer system 110 can generate satisfiability problems 132 in various ways. The computer system 110 can generate the satisfiability problems 132 one at a time, as needed for the current design parameter, e.g., value of number of transistors 130, to be tested next. As another example, the computer system 110 may generate the satisfiability problems 132 in a batch, allowing the different satisfiability problems 132 to be more easily issued, queued, or otherwise invoked with low latency or in parallel.

Each satisfiability problem 132 includes (1) the Boolean expression(s) for the possible wiring combinations for the given design parameter value (e.g., a particular number of transistors) and (2) an assertion or axiom that the circuit is faulted, meaning that the circuit designs represented by the Boolean expression cannot accurately provide the circuit behavior defined by the circuit behavior data 120 (e.g., logic truth table). In other words, the state of “faulted” here means that the entire set of circuit designs represented by the Boolean expression—all possible sets of wiring represented by all possible combinations of values for the Boolean variables in the Boolean expression—fail to provide the full accurate set of circuit behavior needed. If the “fault” condition is found for a satisfiability problem 132, it means that all of the circuit variations represented by the different combinations of values for the variables in the Boolean expression result in at least one failure to provide the full circuit behavior of the circuit behavior data 120.

With the “fault” assertion, a successful circuit design will be found when the satisfiability problem 132 is determined to have a result or classification of “unsatisfiable.” A “satisfiable” result indicates that all possible designs with the given design parameter value (e.g., a class of designs each having the same particular number of transistors) are faulted in some way (e.g., failing to provide the full set of circuit behavior or logic desired for the circuit). When the satisfiability problem 132 is found to be “unsatisfiable,” this means that there is at least one combination of values for the Boolean expression for which the proper logic or circuit behavior is accurately provided, and so the condition of all variations being faulted cannot be satisfied. Because the variables in the Boolean expression represent different circuit wiring connections among a set of transistors, the set of Boolean variable values that lead to the “unsatisfiable” result for the satisfiability problem 132 specify a set of circuit wiring connections that provide a functionally valid circuit (e.g., where each “true” or “1” value represents a wiring connection for the corresponding pair of nodes, and each “false” or “0” connection represents the absence of a connection between the corresponding pair of nodes). Of course, there may be multiple different combinations of Boolean variable values that result in the satisfiability problem 132 being unsatisfiable, and thus there may be multiple different circuit wiring combinations that lead to a functionally valid or potentially usable design. When the SAT solver 124 identifies these combinations, the computer system 110 saves those combinations of variable values as designs that can be used or further verified or optimized.

After a satisfiability problem 132 has been determined for a first circuit size class, e.g., 50 transistors, the computer system 110 tests smaller circuit size classes by updating the satisfiability problem to progressively add assertions that constrain the size of the circuit. For example, after finding that a valid design is possible for 50 transistors, the system adds an assertion that one of the transistors is disconnected (e.g., any one of the transistors, or a particular one such as the 50th transistor). This maintains the same search space as the original satisfiability problem for 50 transistors, but narrows the possible solution to use 49 transistors or fewer. If a valid circuit design is found using 49 transistors, then the satisfiability problem 132 is updated to assert that two transistors are disconnected, and so on. This process can proceed until a size is reached in which no valid circuit design is found, and so the previously tested size is known to be optimal.

The computer system 110 can store and apply design rules 123 that specify general constraints on the design or functioning of a circuit. The design rules 123 specify criteria for a circuit that are separate from the logic specified by the circuit behavior data 120, and typically are shared for use among many different circuit design tasks. In general, the design rules 123 can capture information that expresses how circuits work, e.g., how the elements operate and what conditions are possible and what conditions are excluded in useful circuits. The design rules 123 can specify restrictions or excluded conditions that that specify features that cannot exist in valid, functioning electronic circuits (e.g., to prevent a short circuit, a circuit design cannot have a node simultaneously connected to power and ground). The design rules 123 can also specify requirements or features that must be included for a circuit design to operate or interface with other systems (e.g., that inputs and outputs must have connections with a certain class of nodes, or must provide a voltage within a certain range).

The design rules 123 can be used to generate the Boolean expressions of the satisfiability problems 132. For example, the satisfiability generator 122 can use the design rules 123 to generate the Boolean expressions so that they remove options for some or all of the excluded conditions to exist, and/or that the Boolean expressions enforce or affirmatively include options for some or all of the required conditions to exist. Applying the design rules 123 can be beneficial to reduce the range of possible design options (e.g., different combinations of wiring considered) and thus reduce the complexity of the processing required when the SAT solver 134 analyzes the satisfiability problems 132.

In addition, or as alternative, the computer system 110 can use the design rules 123 in the processing of the SAT solver 124, as an additional constraint, along with the Boolean expression and the assertion that the resulting circuit is faulted. For example, in some implementations, the SAT solver 124 can apply the design rules 123 when analyzing a satisfiability problem 132 and if the design rules 123 cannot be satisfied under any set of Boolean variable values, or at least not any set of Boolean variable values that would make the Boolean expression true, then this can provide a basis for finding the circuit to be always faulted. The SAT solver 124 can advantageously use this feature to optimize the processing of the satisfiability problems 132 and more efficiently identify branches of the search space (e.g., set of circuit wiring variations) that do not meet one or more of the design rules 123 and so further evaluation of those branches can be avoided. In this way, combinations of variable values that would violate the design rules 123 (e.g., by causing a short circuit) can be identified and designated to represent a faulted circuit.

In stage (E), the computer system 110 uses the SAT solver 124 to analyze or evaluate one or more satisfiability problems 132. The SAT solver 124 can be a modified SAT solver 124, configured to more fully address problems in the Σ_{P}² space. Typically, using the SAT solver includes evaluating a first Boolean satisfiability problem 132 for a first size class (e.g., 50 transistors), and then evaluating updated versions of the first Boolean satisfiability problem that progressively constrain a design parameter, such as to incrementally reduce the circuit size over multiple processing iterations (e.g., to 49 transistor, then to 48 transistors, then to 47 transistors, etc.). In this process, the progressive changes to the design constraints are made while preserving the overall search space of the first Boolean satisfiability problem 132 (e.g., for 50 transistors, the largest circuit size tested). The SAT solver 124 also reuses the retained results 125 for the search space that have been accumulated so far. This can provide much greater efficiency than performing the satisfiability analysis for each of the circuit size classes separately. Although a significant amount of processing is performed initially for the first satisfiability problem 132, the amount of processing required is limited for each later processing iteration, which updates the satisfiability problem 132 to require another transistor to be disconnected.

The processing done to find at least one circuit for the larger problem (e.g., 50 transistors) has already examined and classified done much of the work for smaller problems encompassed within the search space (e.g., 49 transistors, 48 transistors, 47 transistors, etc.). A solution that uses 50 transistors will be different from a solution that uses 45 transistors, so there will often be additional processing performed for processing iteration. Nevertheless, portions of the search space that the SAT solver 124 is able to rule out or verify can be reused to reduce the amount of computation for further processing in the same search space.

As noted above, each satisfiability problem 132 includes the same Boolean expression (or set of expressions) representing the class or category of circuit designs encompassed by one or more design parameter values (e.g., in the illustrate example, 50 transistors) and the requirement that all of the variations or Boolean variable combinations represent a circuit that is faulted (e.g., fails at least one aspect of the required circuit behavior specified in the circuit behavior data 120, or violates the design rules 123). After the first processing iteration representing the initial circuit size class tested (e.g., 50 transistors), the satisfiability problem 132 is updated for each successive processing iteration to include an assertion that an additional transistor is disconnected, thus constraining the set of circuit designs to a smaller circuit size while remaining in the original search space of the original satisfiability problem 132.

In the example, processing the satisfiability problem 132 for the circuit size class of 50 transistors yields a “unsatisfiable” or “UNSAT” result, so the SAT solver 124 has identified a valid circuit design found for this circuit size. This circuit design is specified by a combination of values for the variables that represent circuit characteristics that provides the desired circuit behavior or logic across the range of possible input values for the circuit. The SAT solver 124 saves the information determined about the search space in the retained results 125.

The computer system 110 then proceeds to perform a series of additional processing iterations to progressively test smaller circuit sizes. The computer system 110 next tests an incrementally smaller circuit size class for 49 transistors, and to do this the computer system 110 updates the satisfiability problem 132 by adding an assertion that one transistor is disconnected. The SAT solver 124 uses the retained results 125 to efficiently evaluate the updated satisfiability problem 132, and provides a classification that the updated satisfiability problem 132 for 49 transistors is also “unsatisfiable” or “UNSAT,” indicating that a valid circuit design has been found for the 49-transistor size class.

The computer system 110 continues testing progressively smaller circuit sizes, each time using and adding to the information learned about the search space in the retained results 125, until reaching a circuit size where the SAT solver 124 indicates that the updated satisfiability problem 132 is as “satisfiable” or “SAT.” In the illustrated example, this occurs for the circuit size class of 32 transistors (e.g., the search space of 50 transistors with an assertion that 18 of the transistor be disconnected). The “satisfiable” result indicates that the assertion of the circuit being faulted is true across all of the different circuit designs in the size class (e.g., the different combinations of values for the variables representing decisions about circuit characteristics), and so there is no valid circuit design possible for the 32-transistor circuit size class. The computer system 110 uses the smallest size class for which there is a valid circuit design, e.g., the 33-transistor size class, and uses this as the minimum circuit size and optimized circuit design. The computer system 110 can obtain from the SAT solver 124 the combination(s) of values for the variables representing design characteristics that did not include any fault with respect to the desired circuit behavior or logic, and use these to specify the circuit design. As discussed above, the values for the variables can specify which nodes in the circuit are connected by wires, and so the combination of values that produced an unsatisfiable result specifies the wiring among devices that would produce a valid circuit. Values for variables representing other circuit characteristics or design decisions can also be determined (e.g., to specify circuit element types or other parameters).

Each satisfiability problem 132 does not specify a particular set of circuit inputs. In processing a satisfiability problem 132 for a circuit size class, each of the different combinations of Boolean variable values represents a different circuit design in the circuit size class. Solving a single satisfiability problem 132 can represent testing each of the different combinations of Boolean variable values across the range of circuit input values that are possible, to determine whether any combination of connections can accurately provide the specified circuit behavior or logic and satisfy the design rules 123.

For example, for each satisfiability problem 132 evaluated, the SAT solver 124 can assess the different members of the class or category of circuit designs (e.g., the different combinations of Boolean variable values) across the range of circuit inputs. If, for a given circuit design (e.g., combination of Boolean variable values), any aspect of the logic or behavior specified by the circuit behavior data 120 is not provided accurately for any of the possible circuit input value combinations, then that circuit design (e.g., combination of variable values) satisfies the faulted requirement and the SAT solver 124 can move on to test the next circuit design in the class or category (e.g., the next combination of variable values). Of course, the SAT solver 124 can use many kinds of optimizations to address groups of circuit designs together, to improve efficiency. For example, a characteristic that is determined to cause a fault for one design can be determined to also disqualify other circuit designs that share the characteristic. In some cases this can be used to reduce the amount of processing required, but in other cases it can be advantageous to fully evaluate the elements of the search space, especially where the results can be saved and re-used for later iterations of satisfiability processing. Many optimizations for SAT solvers generally, such as backtracking-based search algorithms, unit propagation, the Davis-Putnam-Logemann-Loveland (DPLL) algorithm, conflict-driven clause learning (CDCL), and others can increase the efficiency of the SAT solver 124.

Each satisfiability problem 132 is defined so that the problem as a whole is satisfiable only if each of the circuit designs in the corresponding circuit size class would be faulted (e.g., fail at least one aspect of the desired circuit behavior or logic for at least one combination of inputs, or would fail one or more design rules 123). This framing of the problem allows the processing of a single satisfiability problem 132 to represent a search through all potential circuit designs having a particular number of devices (e.g., transistors, logic gates, etc.). Consequently, if processing the satisfiability problem 132 yields a result of “unsatisfiable,” this indicates that there is at least one valid circuit design in the corresponding circuit design class, e.g., there is at least one combination of values for the variables that represent design decisions for which there are no faults across the range of inputs for the circuit. When a valid circuit design is found, the satisfiability problem 132 is unsatisfiable because the axiom that the circuit must be faulted has not been satisfied.

The SAT algorithm can be used to iterate over or evaluate different circuit designs (e.g., different wiring arrangements within a satisfiability problem 132, represented by different values for the variables in the satisfiability problem 132) in a circuit size class. First, the SAT solver 124 can select a branch variable and a value for that branch variable. The solver attempts to always branch on a design choice if possible. Second, the SAT solver 124 can perform unit propagation. If successful, and if all variables have been assigned values, the SAT solver 124 learns the negation of the design choice made (e.g., learn that the previous variable value does not permit a valid circuit) and backtracks through the branching hierarchy of design choice values (e.g., Boolean variable value assignments). This signifies that it was possible to fault the design corresponding to previous choices, so it is correct to abandon that design and move on to other possibilities. If not successful, the SAT solver 124 returns to the first step. The SAT solver 124 can manipulate the reasons given for a classification or the tree structure representing the search space.

In the analysis process, if the SAT solver 124 backtracks to a design choice, the system has found a successful result. In other words, the SAT solver 124 backtracked to a point where the only choices were design choices, and the theory “below” that in the tree of design choices was “unsatisfiable” (meaning that they could not be faulted with respect to the logic or behavior required). This is the co-NP part of the processing, and the SAT solver 124 has effectively validated those design choices. As the process proceeds, the SAT solver 124 can backtrack as appropriate or fail. If the process results in all possible designs in the class being faulted, then the satisfiability problem 132 being considered is determined to be “satisfiable,” meaning that all designs in the class or category (e.g., sharing the same design parameter such as the current number of transistors being considered) are faulted or incapable of providing the desired behavior.

The SAT solver 124 can be configured to continue processing through the full range of variable value combinations, even when one combination of variable values is found that indicates satisfiability. In many SAT solvers, finding a branch of the search space or a combination of values that evaluates to true would be sufficient to end processing, because one instance of where the problem is satisfied indicates that the problem as a whole is satisfiable. In the system 100, the satisfiability problem 132 should be indicated satisfiable not if a single combination of variable values evaluates to true (including by meeting the circuit fault axiom), but if all combinations of variable values that meet the design rules 123 evaluate to true. As a result, the SAT solver 124 is configured to continue processing a satisfiability problem 132 through the different possible circuit designs in the circuit size class (e.g., the different combinations of values for variables representing circuit characteristics or circuit design decisions), even as the Boolean expressions and the circuit fault axiom evaluate to true.

In some implementations, the computer system 110 performs the combination of steps from stages (C) to (E) repeatedly or iteratively. For example, each iteration can identify the next design parameter value to test (e.g., the next number of transistors 130) in stage (C), to generate a corresponding updated satisfiability problem 132 in stage (D), and to evaluate the generated satisfiability problem 132 with the SAT solver 124 in stage (E). If the result is “unsatisfiable” or “UNSAT,” as illustrated for the circuit sizes 50 transistors through 33 transistors, then another iteration of these operations from stages (C) to (E) is performed. Once the circuit size decreases to the point that the corresponding satisfiability problem 132 has a result of “satisfiable” or “SAT”, then the computer system 110 identifies and saves the circuit design for the smallest size with an “UNSAT” result. This circuit design is specified by the combination values of Boolean variable values representing circuit design decisions that do not result in a fault with respect to the circuit behavior data 120 and which also satisfy the design rules 123. The computer system 110 can propose the identified set of design choices as a circuit design to the user 1024, or can use the identified circuit design to further test and optimize.

When the series of iterations incrementally decreases the size of the circuit designs being analyzed, the last circuit size class (e.g., smallest size class) that has an unsatisfiable result can indicate an optimized solution. For example, in the illustrated example, the circuit size is decreased by one for each of the different processing iterations. Finding that the circuit size class of 33 transistors is the smallest for which the corresponding satisfiability problem 132 is unsatisfiable indicates that 33 transistors is the minimum number needed to provide the logic specified by the user 104.

For other search strategies, the system may use larger increments than one or skip testing (e.g., varying sizes of increments) of some design parameter values (e.g., testing circuit sizes of 64, 32, 16, 8, etc., or testing circuit sizes of 25, 20, 15, 10, etc.). For these approaches, after finding an unsatisfiable result, the first iteration resulting in an satisfiable result would provide a lower bound on the minimum size (e.g., the minimum size would necessarily be larger than the circuit size yielding a result of “satisfiable”). In these cases, the computer system 110 may adjust the design parameter value incrementally until the lowest unsatisfiable result is identified, demonstrating the boundary or minimum level of complexity for which a workable design is possible.

In stage (F), the computer system 110 specifies a circuit design using the results of the SAT solver 124 for the selected size class, e.g., the smallest size class for which an “unsatisfiable” classification is determined. For example, the set of Boolean variable values that lead to the “unsatisfiable” result can be translated to connections in a circuit, which can be saved as design parameters 140 or validation results. The design parameters 140 can be specified in any appropriate form, e.g., diagram, netlist file, etc.

In stage (G) the computer system 110 provides the design parameters 140 or validation results to the user's device 102 over the network 106.

In general, many standard SAT solving techniques can be used for the circuit design features of the system. Some principles or adjustments can improve performance. One option is to optimize the branch order for configurations tested. Whenever the solver can choose to value one variable over another, it is preferred to make the design choices first, then see if there is a failure. Ideally, the cases where failures or faults with respect to the desired behavior occur can be identified early, so the solver 124 can prune the search tree. Ordering the design choices so failure shows up early is best. Another technique is for the SAT solver 124 to not stop at the fringe or bottom of the search tree. In many typical use cases for SAT solvers, if the solver reaches the bottom of the search tree and nothing fails, then the evaluation is done. By contrast, for the satisfiability problems 132, the system can attempt to cover more of the search space with each processing iteration.

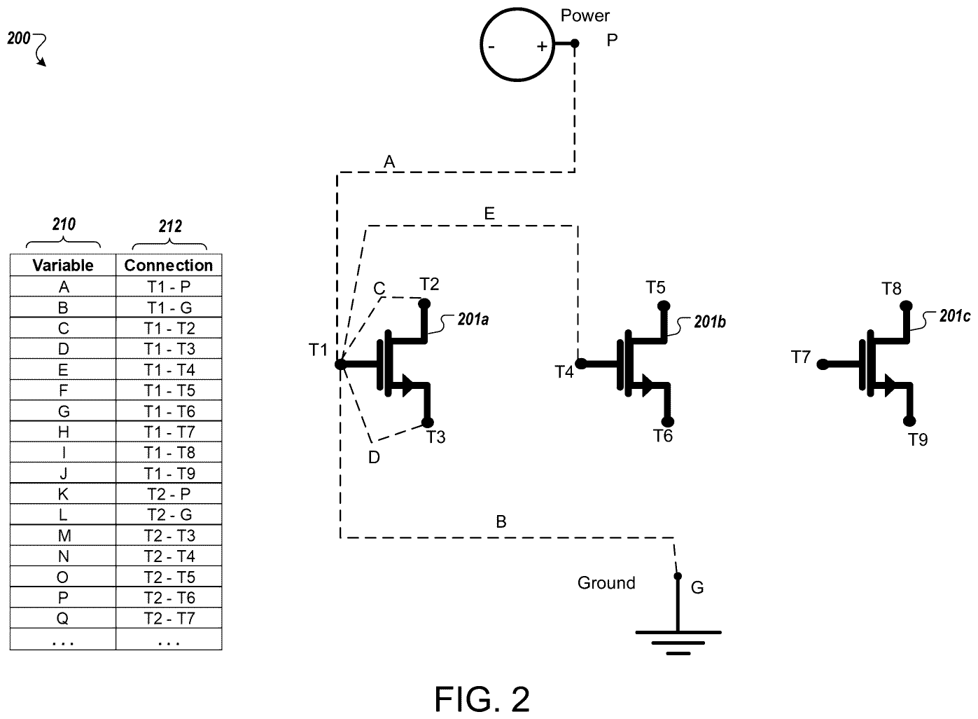

FIG. 2 is a diagram 200 showing an example of circuit design using a SAT solver. The example shows a simple example of how variables in Boolean expressions can be used to represent decisions about whether to connect different nodes in circuits.

The illustrated example shows three transistors 201a-501c as well as nodes for power P and ground G. Each of the transistors is shown as a p-mos transistor with three terminals, e.g., transistor 201a has terminals T1-T3, transistor 201b has terminals T4-T6, and transistor 201b has terminals T7-T9. To define a satisfiability problem 132 for the circuit size class of three transistors, the computer system 110 can define variables 210 for the possible connections 212 between different pairs of nodes that can be connected (e.g., potential wires between any two of the terminals T1-T9, power P, and ground G).

For example, the Boolean variable A represents a decision whether to connect terminal T1 to power P, where a value of “0” or false indicates no connection and a value of “1” or true indicates that a wire connects terminal T1 to power P. Similarly, Boolean variable B represents a decision whether to connect terminal T1 to ground G, Boolean variable C represents a decision whether to connect terminal T1 to terminal T2, and so on. The computer system 110 can create the variables 210 representing some or all of the potential connections 212 that can be made among devices (e.g., transistors, logic gates, modules) of the size class of the satisfiability problem being generated. In some cases, the computer system 110 can start by creating variables for every different pair of nodes, and then by pruning or filtering to remove nodes that represent connections that do not satisfy the design rules 123 (e.g., to remove a variable for connecting power P and ground G, because this would create a short circuit and is not permitted).

With the variables 210 defined for the various possible connections 212 (e.g., connections that are permitted according to the design rules 123), the computer system 110 can generate one or more Boolean expressions to represent the class of circuit designs having three transistors, with one Boolean satisfiability problem 132 representing all of the potential designs for this size class. In processing the Boolean satisfiability problem 132, each of the different combinations of values for the variables 210 would be tested for each of the different combinations of circuit input values that can be provided. As a result, processing the Boolean satisfiability problem 132 tests each of the different circuit designs in the size class to determine whether the desired circuit behavior or logic is present for all different circuit input value combinations.

If the Boolean satisfiability problem 132 with the assertion of a faulted circuit is found to be satisfiable by the SAT solver 124, meaning that all different possible designs have a fault, then the current size class is determined to be too small to provide the desired circuit behavior or logic, and the computer system 110 generates a satisfiability problem 132 for a larger size class (e.g., 1 transistors, rather than the 3 transistors shown in FIG. 2). This will include creating and using additional variables for additional possible connections between pairs of nodes that exist in the larger circuit size class.

On the other hand, if the Boolean satisfiability problem 132 evaluates to unsatisfiable, then the computer system 110 has found a circuit size that can provide the desired circuit behavior or logic. In addition, the computer system 110 can save and us the set of values for the variables 210 that is identified as not meeting the circuit fault axiom (e.g., the values specifying connections that provide the desired circuit behavior or logic across the full range of circuit input values, and so the circuit fault axiom is not satisfied). The identified set of values for the variables 210 defines which connections 212 should be completed and which should not, thus providing a circuit design for the desired circuit behavior or logic.

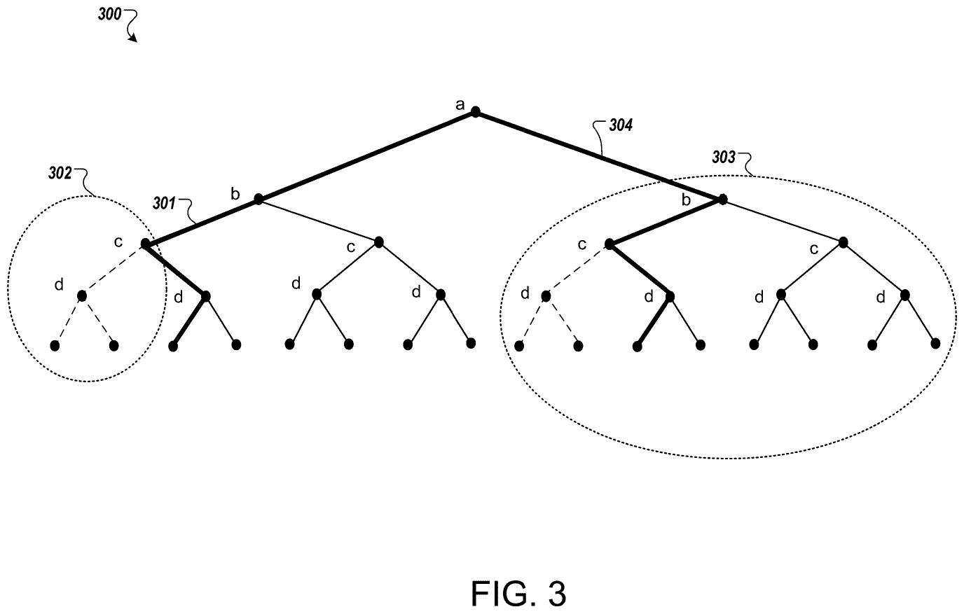

FIG. 3 is a diagram showing an example of a binary tree 300 representing a search space for circuit design using a SAT solver. The search space for solving a Boolean satisfiability problem can be represented as a binary tree where each branch decision represents the two different possible values (e.g., true and false) of a variable. Using the techniques discussed above for FIG. 1, the SAT solver 124 can store retained results 125 from one or more processing iterations that evaluate a search space, and use those results 125 to efficiently solve other problems that involve the search space.

The binary tree 300 is a very simple example with four variables, a, b, c, and d. During processing of an initial satisfiability problem, the SAT solver 124 determined a solution 301 representing a valid design, having variables a, b, and d being true, and with variable c being false. The solution 301 represents a combination of values that would cause the satisfiability problem to be unsatisfiable, and thus represent a correct circuit design, because this combination of design choices would not result in a fault or deviation from the circuit's desired behavior or logic. The processing for the satisfiability problem also determined that a subtree 302 in which variable c is true cannot be part of a valid design.

Using the techniques discussed for FIG. 1, after finding a valid design for one circuit size, the computer system 110 can evaluate a updated version of the satisfiability problem, in which an added assertion requires an element of the circuit to be disconnected or unused. This added assertion updates the satisfiability problem to represent a smaller circuit size while maintaining the same search space used for the original satisfiability problem. In the example, adding the assertion requires the value of variable a to be false, and so limits the updated version of the satisfiability problem to have a solution in a different branch 303 of the binary tree 300. Nevertheless, the processing done previously that excludes paths in which variable c is true removes the corresponding subtree 302 from the branch 303, without needing to perform that processing again for the second processing iteration for the updated satisfiability problem. To the extent that other paths or subtrees have been excluded through processing for previous versions of the satisfiability problem, the retained results 125 accelerate processing of subsequent versions of the satisfiability problem.

In the example, based on the previous processing results 125 and additional processing for the updated version of the satisfiability problem, a second solution 304 is found, representing a valid design that uses fewer circuit elements than the original solution 301.

A number of implementations have been described. Nevertheless, it will be understood that various modifications may be made without departing from the spirit and scope of the disclosure. For example, various forms of the flows shown above may be used, with steps re-ordered, added, or removed.

Embodiments of the invention and all of the functional operations described in this specification can be implemented in digital electronic circuitry, or in computer software, firmware, or hardware, including the structures disclosed in this specification and their structural equivalents, or in combinations of one or more of them. Embodiments of the invention can be implemented as one or more computer program products, e.g., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal that is generated to encode information for transmission to suitable receiver apparatus.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a tablet computer, a mobile telephone, a personal digital assistant (PDA), a mobile audio player, a Global Positioning System (GPS) receiver, to name just a few. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD-ROM and DVD-ROM disks. The processor and the memory can be supplemented by, or incorporated in, special purpose logic circuitry.

To provide for interaction with a user, embodiments of the invention can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

Embodiments of the invention can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the invention, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

1. A method of electronic design automation performed by one or more computers, the method comprising:
accessing, by the one or more computers, circuit data describing circuit behavior or logic for a circuit to be designed;
generating, by the one or more computers, one or more Boolean expressions with variables that each represent a different design characteristic for the circuit, wherein, for each of at least some of the variables, the variable represents a decision whether a connection is made between a corresponding pair of nodes in the circuit;
defining, by the one or more computers, a Boolean satisfiability problem for the class of circuits having a predetermined circuit size, wherein the Boolean satisfiability problem has criteria that include (i) the generated one or more Boolean expressions and (ii) an assertion that the circuit is faulted;
using, by the one or more computers, a Boolean satisfiability solver to process the Boolean satisfiability problem;
after the Boolean satisfiability solver indicates that the Boolean satisfiability problem is unsatisfiable, using, by the one or more computers, the Boolean satisfiability solver to solve a series of updated versions of the Boolean satisfiability problem,
wherein the updated versions of the Boolean satisfiability problem progressively reduce the circuit size compared to the previous version of the Boolean satisfiability problem while maintaining a search space of the Boolean satisfiability problem, and
wherein the Boolean satisfiability solver is configured to store analysis results for the search space and to use the stored analysis results to perform the updated versions of the Boolean satisfiability problem; and
generating, by the one or more computers, circuit design parameters for the circuit based on results of a processing iteration for which the corresponding version of the Boolean satisfiability problem is determined to be unsatisfiable based on the processing of the Boolean satisfiability solver.

2. The method of claim 1, wherein using the Boolean satisfiability solver to solve the series of updated versions of the Boolean satisfiability problem comprises:
processing updated versions of the Boolean satisfiability problem for progressively smaller circuit sizes until obtaining a result for an updated version of the Boolean satisfiability problem that is indicated to be satisfiable based on the processing of the Boolean satisfiability solver;
wherein the generated circuit design parameters comprise a circuit design determined for the smallest circuit size for which the corresponding updated version of the Boolean satisfiability problem is determined to be unsatisfiable.

3. The method of claim 1, wherein the updated versions of the Boolean satisfiability problem each add an assertion that an additional element of the circuit is disconnected or unused.

4. The method of claim 1, wherein the predetermined circuit size is a predetermined number of transistors or logic gates; and
wherein the series of updated versions of the Boolean satisfiability problem is a series of series of updated versions of the Boolean satisfiability problem that respectively include assertions that progressively greater numbers of transistors or logic gates, of the predetermined number of transistors or logic gates, be disconnected or unused.

5. The method of claim 1, wherein generating the circuit design parameters comprises selecting a circuit size corresponding to the processing iteration for the smallest circuit size for which the corresponding updated version of the Boolean satisfiability problem is determined to be unsatisfiable.

6. The method of claim 1, wherein generating the circuit design parameters comprises:
identifying, for the processing iteration for the smallest circuit size for which the corresponding updated version of the Boolean satisfiability problem is determined to be unsatisfiable, a combination of values for the variables of the Boolean expressions for the corresponding Boolean satisfiability problem that does not satisfy the assertion that the circuit is faulted; and
generating data indicating a set of connections among nodes in the circuit based on the identified combination of values.

7. The method of claim 1, wherein the circuit data comprises combinatorial logic for the circuit or a truth table for the circuit.

8. The method of claim 1, wherein the assertion that the circuit is faulted is a requirement that the Boolean satisfiability problem is satisfiable only if there is no combination of values for the variables for which all combinations of the inputs would produce the circuit behavior or logic indicated by the circuit data.

9. The method of claim 1, wherein using the Boolean satisfiability solver to process the Boolean satisfiability problem comprises:
evaluating different combinations of values for the variables representing different design characteristics, including, for each combination of values of the different combinations of values:
evaluating multiple combinations of circuit input values to determine whether, for a circuit having the set of design characteristics indicated by the combination values, each of the multiple combinations of circuit input values would result in circuit output that is specified for the circuit by the circuit data.

10. The method of claim 1, comprising:
accessing a set of design rules for the circuit; and
using the design rules to (i) generate one or more of the Boolean expressions in the sets of Boolean expressions or (ii) limit a set of combinations of values for the variables of the Boolean expressions.

11. A system comprising:
one or more computers; and
one or more computer-readable media storing instructions that are operable, when executed by the one or more computers, to cause the system to perform operations comprising:
accessing, by the one or more computers, circuit data describing circuit behavior or logic for a circuit to be designed;
generating, by the one or more computers, one or more Boolean expressions with variables that each represent a different design characteristic for the circuit, wherein, for each of at least some of the variables, the variable represents a decision whether a connection is made between a corresponding pair of nodes in the circuit;
defining, by the one or more computers, a Boolean satisfiability problem for the class of circuits having a predetermined circuit size, wherein the Boolean satisfiability problem has criteria that include (i) the generated one or more Boolean expressions and (ii) an assertion that the circuit is faulted;
using, by the one or more computers, a Boolean satisfiability solver to process the Boolean satisfiability problem;
after the Boolean satisfiability solver indicates that the Boolean satisfiability problem is unsatisfiable, using, by the one or more computers, the Boolean satisfiability solver to solve a series of updated versions of the Boolean satisfiability problem,
wherein the updated versions of the Boolean satisfiability problem progressively reduce the circuit size compared to the previous version of the Boolean satisfiability problem while maintaining a search space of the Boolean satisfiability problem, and
wherein the Boolean satisfiability solver is configured to store analysis results for the search space and to use the stored analysis results to perform the updated versions of the Boolean satisfiability problem; and
generating, by the one or more computers, circuit design parameters for the circuit based on results of a processing iteration for which the corresponding version of the Boolean satisfiability problem is determined to be unsatisfiable based on the processing of the Boolean satisfiability solver.

12. The system of claim 11, wherein using the Boolean satisfiability solver to solve the series of updated versions of the Boolean satisfiability problem comprises:
processing updated versions of the Boolean satisfiability problem for progressively smaller circuit sizes until obtaining a result for an updated version of the Boolean satisfiability problem that is indicated to be satisfiable based on the processing of the Boolean satisfiability solver;
wherein the generated circuit design parameters comprise a circuit design determined for the smallest circuit size for which the corresponding updated version of the Boolean satisfiability problem is determined to be unsatisfiable.

13. The system of claim 11, wherein the updated versions of the Boolean satisfiability problem each add an assertion that an additional element of the circuit is disconnected or unused.

14. The system of claim 11, wherein the predetermined circuit size is a predetermined number of transistors or logic gates; and
wherein the series of updated versions of the Boolean satisfiability problem is a series of series of updated versions of the Boolean satisfiability problem that respectively include assertions that progressively greater numbers of transistors or logic gates, of the predetermined number of transistors or logic gates, be disconnected or unused.

15. The system of claim 11, wherein generating the circuit design parameters comprises selecting a circuit size corresponding to the processing iteration for the smallest circuit size for which the corresponding updated version of the Boolean satisfiability problem is determined to be unsatisfiable.

16. The system of claim 11, wherein generating the circuit design parameters comprises:
identifying, for the processing iteration for the smallest circuit size for which the corresponding updated version of the Boolean satisfiability problem is determined to be unsatisfiable, a combination of values for the variables of the Boolean expressions for the corresponding Boolean satisfiability problem that does not satisfy the assertion that the circuit is faulted; and
generating data indicating a set of connections among nodes in the circuit based on the identified combination of values.

17. The system of claim 11, wherein the circuit data comprises combinatorial logic for the circuit or a truth table for the circuit.

18. The system of claim 11, wherein the assertion that the circuit is faulted is a requirement that the Boolean satisfiability problem is satisfiable only if there is no combination of values for the variables for which all combinations of the inputs would produce the circuit behavior or logic indicated by the circuit data.

19. The system of claim 11, wherein using the Boolean satisfiability solver to process the Boolean satisfiability problem comprises:
evaluating different combinations of values for the variables representing different design characteristics, including, for each combination of values of the different combinations of values:
evaluating multiple combinations of circuit input values to determine whether, for a circuit having the set of design characteristics indicated by the combination values, each of the multiple combinations of circuit input values would result in circuit output that is specified for the circuit by the circuit data.

20. One or more non-transitory computer-readable media storing instructions that are operable, when executed by one or more computers, to cause the one or more computers to perform operations comprising:
accessing, by the one or more computers, circuit data describing circuit behavior or logic for a circuit to be designed;
generating, by the one or more computers, one or more Boolean expressions with variables that each represent a different design characteristic for the circuit, wherein, for each of at least some of the variables, the variable represents a decision whether a connection is made between a corresponding pair of nodes in the circuit;
defining, by the one or more computers, a Boolean satisfiability problem for the class of circuits having a predetermined circuit size, wherein the Boolean satisfiability problem has criteria that include (i) the generated one or more Boolean expressions and (ii) an assertion that the circuit is faulted;
using, by the one or more computers, a Boolean satisfiability solver to process the Boolean satisfiability problem;
after the Boolean satisfiability solver indicates that the Boolean satisfiability problem is unsatisfiable, using, by the one or more computers, the Boolean satisfiability solver to solve a series of updated versions of the Boolean satisfiability problem,
wherein the updated versions of the Boolean satisfiability problem progressively reduce the circuit size compared to the previous version of the Boolean satisfiability problem while maintaining a search space of the Boolean satisfiability problem, and
wherein the Boolean satisfiability solver is configured to store analysis results for the search space and to use the stored analysis results to perform the updated versions of the Boolean satisfiability problem; and
generating, by the one or more computers, circuit design parameters for the circuit based on results of a processing iteration for which the corresponding version of the Boolean satisfiability problem is determined to be unsatisfiable based on the processing of the Boolean satisfiability solver.
